(19) United States
(12) Patent Application Publication
(10) Pub. No.: US 2025/0309271 A1
(43) Pub. Date: Oct. 2, 2025

(54) METHOD OF MANUFACTURING SOLID-STATE BATTERY

(71) Applicant: HONDA MOTOR CO., LTD., Tokyo (JP)

(72) Inventors: Keisuke TOMIDA, Saitama (JP); Satoshi YONEZAWA, Saitama (JP); Shohei YOSHIDA, Saitama (JP)

(21) Appl. No.: 19/052,309

(22) Filed: Feb. 13, 2025

(30) Foreign Application Priority Data
Mar. 29, 2024 (JP) 2024-056897

(51) Int. Cl. H01M 4/62; G01R 31/385; H01M 4/04

(52) U.S. Cl. CPC H01M 4/624; H01M 4/043; H01M 4/0471; G01R 31/3865

(57) ABSTRACT

To provide a method of manufacturing a solid-state battery capable of improving the strength of a solid electrolyte layer and suppressing the deterioration of battery performance. A method of manufacturing a solid-state battery including a positive electrode layer, a solid electrolyte layer, and a negative electrode layer. The solid electrolyte layer includes a solid electrolyte and a filling material. The filling material includes an easily meltable material having a melting point or a melting temperature of less than 150° C. The method includes determining whether or not a crack has occurred in the solid electrolyte layer, and heating the solid-state battery when it is determined that a crack has occurred in the solid electrolyte layer.

### BACKGROUND OF THE INVENTION

### Field of the Invention

The present invention relates to a method of manufacturing a solid-state battery.

### Related Art

In recent years, research and development has been conducted on secondary batteries that contribute to energy efficiency in order to ensure that more people have access to affordable, reliable, sustainable, and advanced energy.

In recent years, techniques have been proposed for solid-state batteries with solid electrolytes that have high energy density and high thermal safety. Japanese Unexamined Patent Application, Publication No. 2020-184438 discloses a technique in which to provide a method of manufacturing a solid electrolyte layer that is difficult to crack, a solid electrolyte layer is formed using a solid electrolyte composition in which a specific amount of a fibrous organic filler having a specific aspect ratio is dispersed, such that a ratio (D50/d) of a median diameter D50 of the organic filler in the solid electrolyte layer to an average length d of the organic filler as a starting material is 1 or more and 5 or less.
Patent Document 1: Japanese Unexamined Patent Application, Publication No. 2020-184438

### SUMMARY OF THE INVENTION

The manufacturing steps of a solid-state battery may include a step of pressing the laminated solid-state electrolyte layers and the electrode layers in order to improve the electrical characteristics of the solid-state battery. In this case, when a reinforcing material such as a filler is included in the solid electrolyte layer, cracks may occur in the solid electrolyte layer during unloading due to a difference in Young's modulus between the reinforcing material and the solid electrolyte particles, resulting in a deterioration in battery performance.

In response to the above issue, an object of the present invention is to provide a method of manufacturing a solid-state battery capable of improving the strength of a solid electrolyte layer and suppressing the deterioration of battery performance.

A first aspect of the present invention relates to a method of manufacturing a solid-state battery including a positive electrode layer, a solid electrolyte layer, and a negative electrode layer. The solid electrolyte layer includes a solid electrolyte and a filling material. The filling material includes an easily meltable material having a melting point or a melting temperature of less than 150° C. The method includes determining whether or not a crack has occurred in the solid electrolyte layer, and heating the solid-state battery when it is determined that a crack has occurred in the solid electrolyte layer.

According to the invention of the first aspect, it is possible to provide a method of manufacturing a solid-state battery capable of improving the strength of the solid electrolyte layer and suppressing the deterioration of battery performance.

In a second aspect of the method of manufacturing a solid-state battery according to the first aspect, heating the solid-state battery includes heating and pressurizing the solid-state battery.

According to the invention of the second aspect, it is possible to preferably fill the crack with the melted easily meltable material.

In a third aspect of the method of manufacturing a solid-state battery according to the first or second aspect, determining whether or not the crack has occurred includes determining that a crack has occurred in the solid electrolyte layer when an electrical characteristic of the solid-state battery is lower than a prescribed threshold. The prescribed threshold is at least one of a predetermined threshold or a threshold determined based on an initial value in a charge and discharge cycle of the solid-state battery.

According to the invention of the third aspect, even when a crack occurs in the solid electrolyte layer, the deterioration of battery performance can be preferably determined.

In a fourth aspect of the method of manufacturing a solid-state battery according to any one of the first to third aspects, the filling material includes a fibrous filler.

According to the invention of the fourth aspect, the filling material can be uniformly dispersed in the solid electrolyte slurry. In addition, it is possible to impart toughness to the solid electrolyte layer and improve strength against external pressure.

In a fifth aspect of the method of manufacturing a solid-state battery according to any one of the first to fourth aspects, the filling material includes a fibrous filler and a coating layer covering a surface of the filler. At least a part of the coating layer includes the easily meltable material.

According to the invention of the fifth aspect, the filling material can be uniformly dispersed in the solid electrolyte slurry. In addition, the cracks that have occurred can be efficiently filled with the easily meltable material.

In a sixth aspect of the method of manufacturing a solid-state battery according to any one of the first to fifth aspects, the easily meltable material is mixed with a material having ion conductivity.

According to the invention of the sixth aspect, it is possible to more preferably suppress the deterioration of battery performance.

### BRIEF DESCRIPTION OF THE DRAWINGS

FIG. 1 is a cross-sectional view schematically showing a laminated structure of a solid-state battery according to an embodiment of the present invention;

FIG. 2 shows a configuration of a filler included in a solid electrolyte layer according to the embodiment;

FIG. 3 is a cross-sectional view schematically showing a state of cracks occurring in the solid electrolyte layer;

FIG. 4 is a micrograph showing cracks occurring in the solid electrolyte layer; and

FIG. 5 is a micrograph showing that the cracks occurring in the solid electrolyte layer are filled with resin.

### DETAILED DESCRIPTION OF THE INVENTION

### <Solid-State Battery>

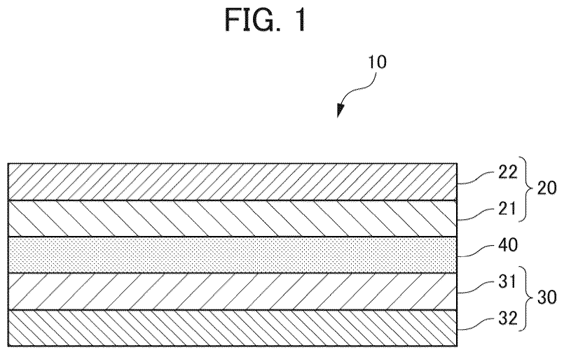

As shown in FIG. 1, a solid-state battery manufactured by the method of manufacturing a solid-state battery according to the present embodiment includes a laminate 10 in which a positive electrode layer 20, a negative electrode layer 30, and a solid electrolyte layer 40 are laminated. Although FIG. 1 shows the laminate 10 in which each of the above layers is laminated one by one, the number of laminated layers is not limited. The laminate 10 is housed in an exterior body such as a laminate film and used as a solid-state battery.

### (Positive Electrode Layer)

The positive electrode layer 20 includes a positive electrode material mixture layer 21 and a positive electrode current collector 22.

The positive electrode material mixture layer 21 includes a positive electrode active material. The positive electrode material mixture layer 21 may further include a solid electrolyte, a conductivity aid, a binder, and the like. The solid electrolyte, the conductivity aid, the binder, and the like are not limited, and substances known as electrode materials for solid secondary batteries can be applied.

The positive electrode active material is not limited, and a substance known as a positive electrode active material for solid secondary batteries can be used. Examples of the positive electrode active material include ternary positive electrode materials such as LiCoO₂, LiNiO₂, and NCM (Li(NiₓCo_{y}Mn_{z})O₂, (0<x<1, 0<y<1, 0<z<1, x+y+z=1)), layered positive electrode active material particles such as LiVO₂ and LiCrO₂, spinel positive electrode active materials such as LiMn₂O₄, Li(Ni_{0.25}Mn_{0.75})₂O₄, LiCoMnO₄, and Li₂NiMn₃O₈, and olivine positive electrode active materials such as LiCoPO₄, LiMnPO₄, and LiFePO₄.

The positive electrode current collector 22 is not limited, and a substance known as a positive electrode current collector for solid secondary batteries can be used. Examples of the positive electrode current collector 22 include metal foils such as stainless steel (SUS) foil and aluminum (Al) foil.

### (Negative Electrode Layer)

The negative electrode layer 30 includes a negative electrode material mixture layer 31 and a negative electrode current collector 32.

The negative electrode material mixture layer 31 includes a negative electrode active material. The negative electrode material mixture layer 31 may further include a solid electrolyte, a conductivity aid, a binder, and the like. The solid electrolyte, the conductivity aid, the binder, and the like are not limited, and substances known as electrode materials for solid secondary batteries can be applied.

The negative electrode active material is not limited, and a substance known as a negative electrode active material for solid secondary batteries can be used. Examples of the negative electrode active material include lithium transition metal oxides such as lithium titanate (Li₄Ti₅O₁₂), transition metal oxides such as TiO₂, Nb₂O₃, and WO₃, metal sulfides, metal nitrides, carbon materials such as graphite, soft carbon, and hard carbon, silicon-based materials such as silicon, silicon alloys, and silicon compounds, as well as lithium metal, lithium alloys, and metallic indium.

The negative electrode current collector 32 is not limited, and a substance known as a negative electrode current collector for solid secondary batteries can be used. Examples of the negative electrode current collector include metal foils such as copper (Cu) foil, stainless steel (SUS) foil and aluminum (Al) foil.

### (Solid Electrolyte Layer)

The solid electrolyte layer 40 includes a solid electrolyte and a filling material. The solid electrolyte layer 40 may include a binder in addition to the above.

Examples of the solid electrolyte include, but are not limited to, a sulfide-based solid electrolyte, an oxide-based solid electrolyte, a nitride-based solid electrolyte, and a halide-based solid electrolyte.

The binder is not limited, and examples thereof include polyvinylidene fluoride (PVDF), polymethyl methacrylate (PMMA), polyisobutene (PIB), styrene-butadiene rubber (SBR), polyethylene-vinyl acetate copolymer (PEVA), nitrile rubber (NBR), and hydrogenated nitrile rubber (HNBR). These may be used alone or in combination of two or more kinds thereof.

### [Filling Material]

The filling material includes an easily meltable material. The filling material improves the strength of the solid electrolyte layer 40, and when cracks occur in the solid electrolyte layer 40, the easily meltable material can be melted and allowed to flow into the cracks, suppressing the deterioration of battery performance.

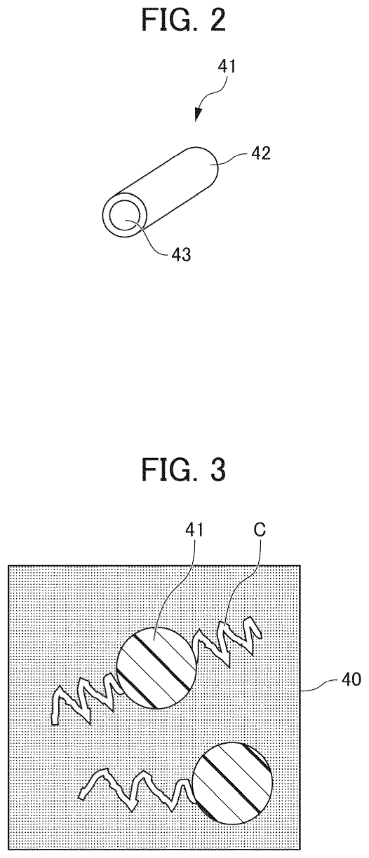

A filling material 41 is not limited as long as it includes an easily meltable material, and may be in the form of particles, but as shown in FIG. 2, it is preferable that the filling material 41 includes a fibrous filler 43 and a coating layer 42 covering the surface of the filler 43, and that the coating layer 42 includes the easily meltable material. As shown in FIG. 3, since it is assumed that a crack C occurs starting from the filling material 41, the presence of the easily meltable material on the surface of the filler 43 allows the easily meltable material to efficiently flow into the crack C.

The filling material 41 including the coating layer 42 and the filler 43 is preferably a single fiber having a minimum length of 1.0 to 10 μm, a maximum length of 100 to 1000 μm, and an aspect ratio of 100 or more. Accordingly, since the filling material 41 can be uniformly dispersed in the solid electrolyte slurry when the solid electrolyte layer 40 is formed, the solid electrolyte layer 40 can be easily formed. In addition, it is possible to impart toughness to the solid electrolyte layer 40 and improve strength against external pressure.

The easily meltable material has a melting point or a melting temperature of less than 150° C. Examples of such an easily meltable material include thermoplastic resins having a melting point of less than 150° C., such as polyethylene, and resins having a melting temperature of less than 150° C., such as polystyrene, polyvinyl chloride, and ABS resins. By using an easily meltable material having a melting point or a melting temperature of less than 150° C., the heating temperature at which cracks occur (described later) can be set to a temperature lower than the degradation temperature of the binder included in the solid electrolyte layer 40.

The easily meltable material is preferably mixed with a material having ion conductivity. This improves ion conductivity when the crack is filled with the easily meltable material, so that the deterioration of battery performance can be more preferably suppressed. Examples of the material having ion conductivity include the solid electrolytes described above.

The filler 43 imparts toughness to the solid electrolyte layer 40 and improves strength against external pressure. As the filler 43, for example, an organic filler can be used. The material constituting the organic filler is not limited, and examples thereof include polyethylene terephthalate (PET), polyamide, polyimide, and polycarbonate. The melting point or the melting temperature of the material constituting the filler 43 is preferably higher than the melting point or the melting temperature of the easily meltable material.

Although the solid-state battery according to the present embodiment is not limited, it is preferably a solid-state battery having large expansion and contraction due to charge and discharge (e.g., a lithium metal solid-state battery) because the method of manufacturing a solid-state battery according to the present embodiment can suppress the deterioration of battery performance due to the occurrence of cracks.

### <Method of Manufacturing Solid-State Battery>

The method of manufacturing a solid-state battery according to the present embodiment includes a crack determination step of determining whether or not a crack has occurred in the solid electrolyte layer 40, and a heating step of heating the solid-state battery when it is determined in the crack determination step that a crack has occurred in the solid electrolyte layer 40. Each of the above steps is performed at least after the steps of forming the positive electrode layer 20, the negative electrode layer 30, and the solid electrolyte layer 40, and the step of integrating the above layers by pressing or the like, that is, the steps of producing a solid-state battery. Further, the method of manufacturing a solid-state battery according to the present embodiment may include a charge and discharge cycle test step for confirming the performance of the solid-state battery.

The steps of forming the positive electrode layer 20 and the negative electrode layer 30 are not limited, and examples thereof include a step of preparing an electrode material mixture slurry and applying the slurry onto a current collector.

The step of forming the solid electrolyte layer 40 includes, for example, the following steps. A binder solution is prepared by dissolving a binder in a solvent such as butyl butyrate, then the binder solution is mixed with a filling material and stirred, then the mixture is mixed with particles of a solid electrolyte and stirred, and the mixture is mixed with a solvent as appropriate to prepare a solid electrolyte slurry. Then, the solid electrolyte slurry is applied to the surface of the electrode layer to form the solid electrolyte layer 40.

The method of integrating the positive electrode layer 20, the negative electrode layer 30, and the solid electrolyte layer 40 by pressing is not limited, and known methods such as uniaxial pressing and roll pressing can be used.

The crack determination step is, for example, a step of measuring an electrical characteristic of the solid-state battery and determining that a crack has occurred in the solid-state electrolyte layer 40 when the electrical characteristic is lower than a prescribed threshold. Examples of the electrical characteristic of the solid-state battery include an internal voltage (V) and a discharge capacity (mAh). The prescribed threshold may be, for example, a predetermined specific threshold, or a threshold determined based on an initial electrical characteristic in a charge and discharge cycle test (e.g., the threshold is determined based on an initial internal voltage or an initial discharge capacity, and as an example, about 94.0% to 95.0% of the initial discharge capacity can be set as the threshold), or a combination thereof. Alternatively, in the crack determination step, whether or not a crack has occurred may be determined based on a difference in Young's modulus between the materials. For example, the crack determination step may be a step of determining that a crack has occurred in the solid electrolyte layer 40 when the difference between the Young's modulus of the solid electrolyte layer 40 and the Young's modulus of the filler 43 is 0.5 GPa or more. This is because, when pressure is applied to the solid electrolyte layer 40 including the filler 43, cracks may occur due to differences in how the solid electrolyte particles and the filler are crushed and how they are restored.

The heating step is a step of heating the solid-state battery when it is determined in the crack determination step that a crack has occurred in the solid-state electrolyte layer. The heating step may be a step of heating and pressurizing the solid-state battery. Accordingly, the crack can be preferably filled with the melted easily meltable material. When it is not determined in the crack determination step that a crack has occurred in the solid electrolyte layer, the heating step is preferably not performed. Accordingly, the deterioration of the solid-state battery can be suppressed.

In the heating step, the temperature at which the solid-state battery is heated is equal to or higher than the melting point or melting temperature of the easily meltable material. The temperature is preferably lower than the degradation temperature of the binder included in the solid electrolyte layer. Specifically, the temperature is preferably set to 50° C. to 150° C. In the heating step, the pressure at which the solid-state battery is pressurized may be, for example, 1 MPa to 60 MPa.

In the heating step, the method of heating the solid-state battery is not limited, and may be a method using a heater or hot air, or may be a method using a heat press when the heating step is a step of heating and pressurizing the solid-state battery.

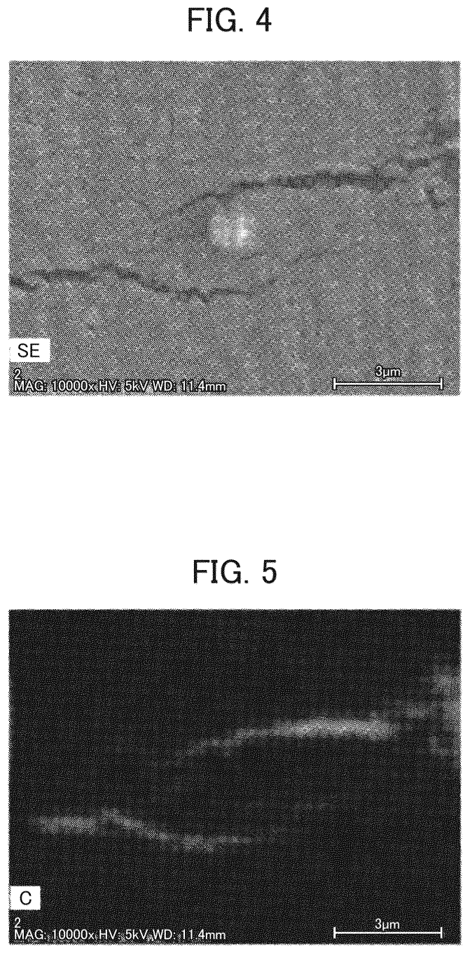

FIGS. 4 and 5 are micrographs showing the results of SEM-EDX mapping analysis (C) of the solid electrolyte layer 40 after heat pressing at 150° C. the solid electrolyte layer 40 in which cracks have occurred (including polyethylene particles having a diameter of about 10 μm as a filling material). The analysis was performed using a field emission scanning electron microscope (FE-SEM)S-4800 (manufactured by Hitachi High-Tech Corporation). FIG. 4 shows an SEM image, and FIG. 5 shows an EDX mapping analysis result.

It is clear from FIGS. 4 and 5 that the cracks occurring in the solid electrolyte layer 40 are filled with carbon (C).

Although the preferred embodiment of the present invention has been described above, the present invention is not limited to the above embodiment, and modifications and improvements within a range capable of achieving the object of the present invention are included in the present invention.

### EXPLANATION OF REFERENCE NUMERALS

10 solid-state battery (laminate)
20 positive electrode layer
30 negative electrode layer
40 solid electrolyte layer
41 filling material
42 coating layer (easily meltable material)
43 filler

What is claimed is:

1. A method of manufacturing a solid-state battery comprising a positive electrode layer, a solid electrolyte layer, and a negative electrode layer,
the solid electrolyte layer comprising a solid electrolyte and a filling material,
the filling material comprising an easily meltable material having a melting point or a melting temperature of less than 150° C.,
the method comprising:
determining whether or not a crack has occurred in the solid electrolyte layer; and
heating the solid-state battery when it is determined that a crack has occurred in the solid electrolyte layer.

2. The method of manufacturing a solid-state battery according to claim 1, wherein heating the solid-state battery comprises heating and pressurizing the solid-state battery.

3. The method of manufacturing a solid-state battery according to claim 1,
wherein determining whether or not the crack has occurred comprises determining that a crack has occurred in the solid electrolyte layer when an electrical characteristic of the solid-state battery is lower than a prescribed threshold, and
wherein the prescribed threshold is at least one of a predetermined threshold or a threshold determined based on an initial value in a charge and discharge cycle of the solid-state battery.

4. The method of manufacturing a solid-state battery according to claim 1, wherein the filling material comprises a fibrous filler.

5. The method of manufacturing a solid-state battery according to claim 1,
wherein the filling material comprises a fibrous filler and a coating layer covering a surface of the filler, and
wherein at least a part of the coating layer comprises the easily meltable material.

6. The method of manufacturing a solid-state battery according to claim 1, wherein the easily meltable material is mixed with a material having ion conductivity.
